(19) United States
(12) Patent Application Publication
(10) Pub. No.: US 2013/0119363 A1
(43) Pub. Date: May 16, 2013

(54) FLUORINE-CONTAINING AROMATIC COMPOUND, ORGANIC SEMICONDUCTOR MATERIAL AND ORGANIC THIN FILM DEVICE

(71) Applicant: ASAHI GLASS COMPANY, LIMITED, Tokyo (JP)

(72) Inventors: Takashi SASAKI, Tokyo (JP); Yoko TAKEBE, Tokyo (JP); Masahiro ITO, Tokyo (JP)

(73) Assignee: ASAHI GLASS COMPANY, LIMITED, Tokyo (JP)

(21) Appl. No.: 13/734,640

(22) Filed: Jan. 4, 2013

Related U.S. Application Data
(63) Continuation of application No. PCT/JP2011/065516, filed on Jul. 6, 2011.

(30) Foreign Application Priority Data
Jul. 8, 2010 (JP) 2010-155980

(51) Int. Cl. H01L 51/00

(52) U.S. Cl. CPC H01L 51/0062
USPC 257/40; 568/633; 549/59

(57) ABSTRACT

A fluorine-containing aromatic compound represented by a formula: Q(W—Ar^{F}(Z)ₖ)ₙ is provided. The Q is an n-valent aromatic hydrocarbon group obtained by removing n-pieces of hydrogen atoms from a monocyclic structure, a polycyclic assembly structure, or a condensed polycyclic structure of one or more benzene rings or heterocycles. The W is a hydrocarbon group having an unsaturated bond of which carbon number is two. The Ar^{F} is a fluorine-containing aromatic hydrocarbon group. The Z is a monovalent organic group selected from —R, —OR, —R^{f}, or the like. The “R” is an alkyl group of which carbon number is one to 12, the “R^{f}” is a fluorine-substituted alkyl group of which carbon number is one to 12.

### CROSS-REFERENCE TO RELATED APPLICATIONS

This application is a continuation of prior International Application No. PCT/JP2011/065516 filed on Jul. 6, 2011, which is based upon and claims the benefit of priority from Japanese Patent Application No. 2010-155980, filed on Jul. 8, 2010; the entire contents of all of which are incorporated herein by reference.

### FIELD

Embodiments of the present invention relate to a new fluorine-containing aromatic compound capable of applying for an organic thin film device, an organic semiconductor material and the organic thin film device.

### BACKGROUND

In recent years, an organic electronics element in which an organic compound is used as a semiconductor material has been remarkably developed. An organic electroluminescence element (hereinafter, referred to as an organic EL element) expected as a flat panel display in a future generation, an organic thin film solar cell as a lightweight and flexible power supply, an organic thin film transistor (hereinafter, referred to as an organic TFT) can be cited as representative applications thereof. The organic TFT attracts attention because a thin film transistor (TFT) used for driving pixels of a display is able to be manufactured by a low cost process such as a printing, and capable of corresponding to a flexible substrate.

The organic compound is easy to process compared to inorganic silicon, and therefore, it is expected to enable a low-price device by using the organic compound as the semiconductor material. Besides, the semiconductor device in which the organic compound is used can be manufactured at a low-temperature, and therefore, it is possible to apply various substrates including a plastic substrate. Further, the semiconductor material of the organic compound (organic semiconductor material) is structurally soft, and therefore, it is expected to enable a device such as a flexible display by combining the plastic substrate and the organic semiconductor material to be used.

In general, improvement in a carrier mobility of the organic semiconductor material is required to enable a long operating life and a low driving voltage of the organic EL element, a low threshold voltage and a switching speed improvement of the organic TFT, and so on. In recent years, a new t conjugated compound made up by bonding aromatic hydrocarbon and fluorine-containing aromatic hydrocarbon group, and an n-type organic semiconductor material excellent in the carrier mobility and so on using the m conjugated compound as a charge transport material have been proposed (refer to WO 2007/145293 A1).

However, a compound described in WO 2007/145293 A1 has not enough solubility for general organic solvents such as chloroform, tetrahydrofuran, toluene, xylene, and therefore, a thin film forming by low cost coating methods such as a spin coating method, an ink-jet method, a printing method has been difficult. Accordingly, there is a problem in which it is difficult to obtain a flexible organic thin film device using a plastic film and so on at low cost.

### SUMMARY OF THE INVENTION

Embodiments of the present invention have been made to solve the problems held by the conventional art, and an object thereof is to provide a π conjugated compound capable of practically being used as an organic semiconductor material, and an organic semiconductor material in which the π conjugated compound is used as a charge transport material, excellent in liquid crystallinity, and capable of being easily applied to a coating process. Besides, another object of embodiments of the present invention is to provide a high-performance organic thin film device containing the organic semiconductor material.

A fluorine-containing aromatic compound represented by the following formula (1) is provided.

QW—Ar^{F}(Z)ₖ)ₙ (1)

Symbols in the formula (1) are as stated below.

Q: An n-valent aromatic hydrocarbon group having a ring structure selected from a monocyclic structure made up of one benzene ring or one heterocycle containing a hetero atom, a polycyclic assembly structure in which two or more pieces of benzene rings or heterocycles are bonded in a single bond, and a condensed polycyclic structure of two or more pieces of benzene rings or heterocycles, and obtained by removing n-pieces of hydrogen atoms bonded to carbon atoms constituting the ring.

n: Two or three.

W: A divalent hydrocarbon group having an unsaturated bond of which carbon number is two.

Ar^{F}: A “k+1”-valent fluorine-containing aromatic hydrocarbon group being a “k+1”-valent group having the monocyclic structure made up of one benzene ring or the condensed polycyclic structure of two or more pieces of benzene rings, and obtained by removing “k+1” pieces of hydrogen atoms bonded to the carbon atoms constituting the ring, and one or more pieces of hydrogen atoms bonded to the carbon atoms constituting the ring are substituted by fluorine atoms.

k: An integer number from one to three.

Z: A monovalent organic group selected from —R, —OR, —CH₂—OR, —R^{f}, —O—(CH₂)ₚ—R^{f}, —CH₂—O— (CH₂)ₚ—R^{f}. Note that the “R^{f}” is an alkyl group of which carbon number is one to 12, the “R^{f}” is a fluorine-substituted alkyl group of which carbon number is one to 12, and the “p” is an integer number from “0” (zero) to two.

An organic semiconductor material comprising the above-stated fluorine-containing aromatic compound is provided.

An organic thin film device, comprising a substrate and an organic thin film transistor having a gate electrode, a gate insulating layer, an organic semiconductor layer, a source electrode and a drain electrode formed on the substrate, in which the organic semiconductor layer contains the above-stated fluorine-containing aromatic compound is provided.

Further, an organic thin film device, comprising a substrate and an organic EL element including an anode, an organic compound layer having a one-layer or more structure, and a cathode formed on the substrate, in which the organic compound layer contains the above-stated fluorine-containing aromatic compound is provided.

### DETAILED DESCRIPTION

Hereinafter, embodiments of the present invention will be described in detail. At first, a fluorine-containing aromatic compound is described.

The fluorine-containing aromatic compound according to a first embodiment of the present invention is a compound represented by the following formula (1). Note that “the compound represented by the formula (1)” is stated as “the compound (1)” in the present description. Besides, “a group represented by a formula (2)” is stated as “a group (2)”, and “a unit represented by a formula (3)” is stated as “a unit (3)”. Further, a word of “aromatic series” used in the present description means not only a benzene ring but also a structure having a conjugated unsaturated ring in which atoms are arranged in a ring state and π electrons are included.

QW—Ar^{F}(Z)ₖ) (1)

In the formula (1), the “Q” is an n-valent aromatic hydrocarbon group obtained by removing n-pieces of hydrogen atoms from structures of the following (i) to (iii).

(i) A monocyclic structure made up of one benzene ring, or one heterocycle containing a hetero atom.
(ii) A polycyclic assembly structure in which two or more pieces of benzene rings or heterocycles are bonded via a single bond.
(iii) A condensed polycyclic structure made up of two or more pieces of benzene rings or heterocycles.
In these structures, a thiophene ring being an unsaturated five-membered ring containing a sulfur atom, a furan ring being an unsaturated five-membered ring containing an oxygen atom, a pyrrole ring being an unsaturated five-membered ring containing a nitride atom, a pyridine ring being an unsaturated six-membered ring containing a nitride atom, and so on can be cited as the heterocycles containing the hetero atom.

### (i) Monocyclic Structure

Benzene represented by the following formula (Q1) can be cited as an example of the monocyclic structure made up of one benzene ring, and thiophene represented by the following formula (Q2) can be cited as an example of the monocyclic structure made up of one heterocycle, respectively.

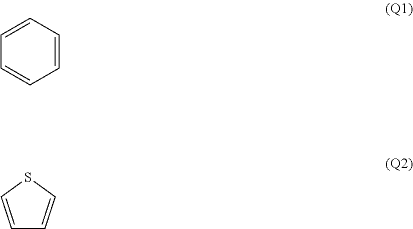 [SMILES: c1ccccc1 ; c1ccsc1]

### (ii) Polycyclic Assembly Structure

Biphenyl represented by the following formula (Q3) can be cited as an example of the polycyclic assembly structure in which two or more pieces of benzene rings are bonded in the single bond. Terthiophene represented by the following formula (Q4) can be cited as an example of the polycyclic assembly structure in which two or more pieces of heterocycles are bonded in the single bond.

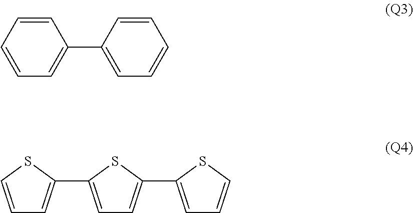 [SMILES: c1ccc(-c2ccccc2)cc1 ; c1csc(-c2ccc(-c3cccs3)s2)c1]

(iii) Condensed Polycyclic Structure

In the condensed polycyclic structure, the numbers of the benzene rings and the heterocycles are not particularly limited, and a total number of rings is to be two or more. It may be the condensed polycycles made up of only the benzene rings, the condensed polycycles made up of only the heterocycles, or the condensed polycyclic structure containing both the benzene ring and the heterocycle. Structures represented by the following formulas (Q5) to (Q9) can be cited as examples of the condensed polycyclic structures.

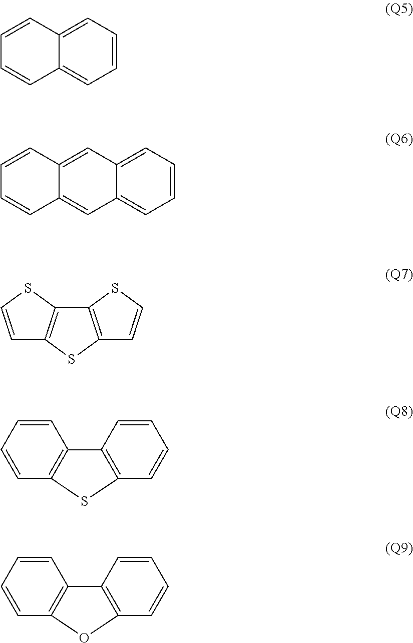

Note that in the “Q” having the structures of (i) to (iii), it is preferable that the hydrogen atoms bounded to the carbon atoms constituting the benzene ring or the heterocycle are non-substitution. Incidentally, in the “Q”, a part of the hydrogen atoms may be substituted by an alkyl group of which carbon atom number is one to eight, preferable to be one to four, or by a fluorine-containing alkyl group of which carbon atom number is one to eight, preferable to be one to four.

In the formula (1), n-pieces of (W—Ar^{F}(Z)ₖ) units are bonded to the “Q”. The “n” is two or three. It is preferable that the “n” is two from a view point of a later-described symmetry of a molecule.

The “W” in the (W—Ar^{F}(Z)ₖ) unit is a divalent hydrocarbon group having a unsaturated bond. The divalent unsaturated hydrocarbon groups of which carbon number is two represented by the following formulas (W1) to (W4) are preferable as the “W”. Note that in the formula, the “X” represents a fluorine atom, a chlorine atom or a cyano group. Besides, the unsaturated hydrocarbon groups represented by the (W1) to (W3) may be either one of a cis type or a trans type. Namely, this part may be either an E type or a Z type. A direction of the unsaturated hydrocarbon group represented by the (W2) may be any direction. Namely, the hydrogen atom may exist at the carbon atoms bonded to the “Q”, or at the carbon atoms bonded to the Ar^{F}. Further, when the compound (1) is used as the organic semiconductor material, and the “W” is the unsaturated hydrocarbon group selected from (W1) to (W3), it is preferable that a mixture of the cis type and the trans type is not used from a point of view of later-described stacking of the molecules with each other.

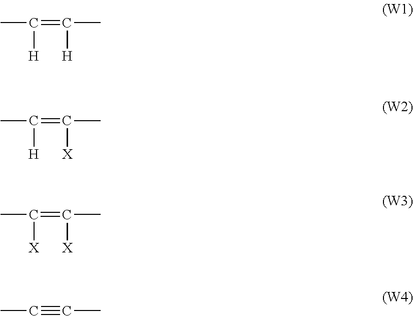

From a point of the charge mobility, it is particularly preferable that the “W” is an ethylenedene group represented by the formula (W4). The “W” is the ethylenedene group, and thereby, a planarity of the molecule made up of the “Q”, the ethylenedene group and the Ar^{F} becomes high. Because the π conjugated system becomes long, and thereby, an interaction between the molecules becomes large, and therefore, it is conceivable that the high charge mobility properties can be obtained.

The Ar^{F} is the “k+1”-valent group having the monocyclic structure made up of one benzene ring or the condensed polycyclic structure of two or more pieces of benzene rings and obtained by removing the “k+1” pieces of hydrogen atoms bonded to the carbon atoms constituting the ring, and is the fluorine-containing aromatic hydrocarbon group in which one or more of the remaining hydrogen atoms bonded to the carbon atoms constituting the ring are substituted by the fluorine atoms. Namely, the Ar^{F} represents the “k+1”-valent fluorine-containing aromatic hydrocarbon group. Note that the “k” is an integer number from one to three. The “k” is preferable to be one from the point of view of the charge mobility. When the “k” is two or three, namely, when the “Z” exists two or three, the k-pieces of “Z” may be the same or different.

The fluorine-containing aromatic hydrocarbon groups represented by the following formulas (A1) and (A2) can be cited as the Ar^{F}(Z)ₖ.

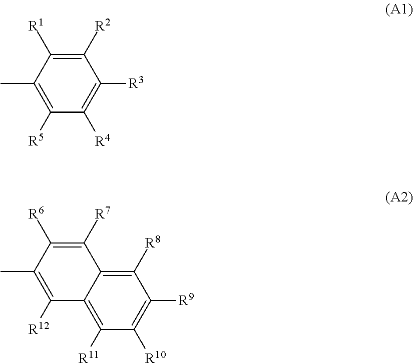

In the aromatic hydrocarbon group (A1), the R¹ to R⁵ represent the hydrogen atoms, the fluorine atoms or the monovalent organic groups “Z”. The k-pieces (for example, one piece) among the R¹ to R⁵ are the monovalent organic groups Z, and at least one of the remaining groups is the fluorine atom. It is preferable that all of the groups except the monovalent organic groups Z are the fluorine atoms. Namely, the (A1) is preferable to be a perfluorophenyl group substituted by the k-pieces of organic groups “Z”.

In the aromatic hydrocarbon group (A2), the R⁶ to R¹² represent the hydrogen atoms, the fluorine atoms or the monovalent organic groups Z. The k-pieces (for example, one piece) among the R⁶ to R¹² are the monovalent organic groups Z, and at least one of the remaining groups is the fluorine atom. It is preferable that all of the groups except the monovalent organic groups Z are the fluorine atoms. Namely, the (A2) is preferable to be a perfluoronaphthyl group substituted by the k-pieces of organic groups “Z”.

The monovalent organic group “Z” bonded to the fluorine-containing aromatic hydrocarbon group Ar^{F} is the monovalent organic group selected from —R, —OR, —CH₂—OR, —R^{f}, —O—(CH₂)ₚ—R^{f}, —CH₂—O—(CH₂)—R^{f}. Here, the “R” is the alkyl group of which carbon number is one to 12. The alkyl group of which carbon number is one to eight is preferable. The R^{f} is the fluorine substituted alkyl group of which carbon number is one to 12 in which at least one of the hydrogen atoms bonded to the carbon atoms is substituted by the fluorine atom. An perfluoroalkyl group of which carbon number is one to eight is preferable. The “p” is an integer number from “0” (zero) to two. The —OR, —CH₂—OR, —O—(CH₂)ₚ—R^{f} are especially preferable as the monovalent organic group “Z”.

The k-pieces of monovalent organic groups Z as stated above are bonded to the benzene ring or the condensed polycyclic structure of the fluorine-containing aromatic hydrocarbon group Ar^{F}, and the group Ar^{F}(Z)ₖ is constituted. A bonding position of the organic group Z is preferable to be the fourth when a bonding position of the “W” for the Ar^{F} is the first with the “k” being one and the Ar^{F}(Z)ₖ being the (A1) from a point of view of the symmetry of the molecules. In this case, the Ar^{F} is preferable to be tetrafluoro-1,4-phenylene group. Besides, when the “k” is one and the Ar^{F}(Z)ₖ is (A2), the bonding position of the organic group Z is preferable to be the sixth when the bonding position of the “W” for the Ar^{F} is the second. In this case, the Ar^{F} is preferable to be hexafluoro-2,6-naphthylene group.

As stated above, the fluorine-containing aromatic compound (I) according to the embodiment of present invention has the structure in which the n-pieces (two or three) of (W—Ar^{F}(Z)ₖ) units are bonded to the “Q” having the monocyclic, polycyclic assembly structure, or condensed polycyclic structure made up of the benzene ring or the heterocycle. The molecules are preferable to be regularly arranged in a crystal structure in the fluorine-containing aromatic compound (1), and therefore, the symmetry of the molecules is preferable to be high, and the “n” is preferable to be two from the point of view of the symmetry of the molecules. When the “n” is two, the bonding position of the (W—Ar^{F}(Z)ₖ) unit at the “Q” is preferable to be the second and the sixth when the “Q” is the (Q5), and it is preferable to be the second and the sixth, or the ninth and the tenth when the “Q” is the (Q6).

Further, in the n-pieces of (W—Ar^{F}(Z)ₖ) units, the “W”, the Ar^{F} and the “Z” in each unit are independent from one another, and the n-pieces of (W—Ar^{F} (Z)ₖ) units may be the same or the different. Namely, the fluorine-containing aromatic compound (1) according to the embodiment may be an asymmetric compound relative to the “Q”. However, it is preferable that the n-pieces of (W—Ar^{F}(Z)ₖ) units are all the same from the point of view of the symmetry of the molecules.

The fluorine-containing aromatic compound (1) constituted as stated above is able to have high carrier mobility and has electron transport properties when it is used for the organic thin film device as the organic semiconductor material. Besides, it represents the liquid crystallinity at a wide temperature range (for example, 1° C. to 300° C., preferable to be 100° C. to 300° C.), and therefore, an uniform film can be obtained at a large area. Namely, it is impossible to obtain a large single crystal corresponding to a film formation area in crystalline molecules, and therefore, it is difficult to obtain an uniform film caused by existences of crystal grain boundaries. However, there is not the crystal grain boundary in a liquid crystalline material, besides it is easy to control an alignment and arrangement of molecules even in a non-crystalline state (solid phase) compared to a general solid body, and therefore, it is possible to easily obtain an uniform optical anisotropic film in a large area. Further, the fluorine-containing aromatic compound (1) has the good solubility for general organic solvents such as chloroform, tetrahydrofuran, toluene, xylene, and therefore, it is possible to form the thin film by the low-cost coating methods such as the spin coating method, the ink-jet method, and the printing method. It is possible to manufacture an organic thin film device having good properties at low-cost by using the fluorine-containing aromatic compound (1).

A manufacturing method of the fluorine-containing aromatic compound (1) is not particularly limited, but it is possible to manufacture by the following method. For example, a case when the “n” is two in the fluorine-containing aromatic compound (1) is exemplified, then it is possible to manufacture by the following (I) or (II) method.

(I) A method using a coupling reaction with an ethynyl compound having an active proton represented by the following reaction formula (a) or (b)

H—C≡C-Q-C≡C—H+2(L-Ar^{F}(Z)ₖ)—(Z)ₖAr^{F}—C≡C-Q-C≡C—Ar^{F}(Z)ₖ+2HL (a)

or

L-Q-L+2(H—C≡C—Ar^{F}(Z)ₖ)→(Z)ₖAr^{F}—C≡C-Q-C≡C—Ar^{F}(Z)ₖ+2HL (b)

Here, the “Q”, the Ar^{F} and the (Z)ₖ represent the same symbols as those in the above-stated formula (1). The “L” represents a leaving group. The leaving group “L” is a halogen atom such as a chlorine atom, a bromine atom, an iodine atom. It is preferable to use a transition metal such as palladium, copper, platinum, nickel, a salt thereof or a complex thereof as a catalyst for the coupling reaction. The catalyst may be used as one kind, or by mixing two or more kinds. As an example using the two or more kinds by mixing, it is cited to use a zerovalent palladium catalyst such as tetrakis (triphenylphosphine) palladium (0) and a transition metal salt such as copper bromide, copper iodide by mixing with each other. Besides, a lithium halide salt such as lithium bromide, lithium iodide may be mixed to the above-stated catalyst.

A solvent capable of capturing generated HL is preferable as the solvent of the above-stated coupling reaction, and an amine-based solvent is generally used. Specifically, for example, triethylamine, diisopropylamine, pyridine, pyrrolidine, piperidine, and so on are used. These may be mixed with the other solvents, and in that case, it is preferable to use an aprotic solvent such as benzene, toluene, tetrahydrofuran as the other solvents.

A reaction temperature of these reactions is preferable to be 30° C. to 150° C. In particular, it is preferable to be performed by heating to approximately 70° C. to 100° C.

A compound represented by the formula: H—C≡C-Q-C≡C—H in the reaction formula (a) is able to be manufactured by, for example, a method represented in the following.

L-Q-L+2(H—C≡C—C(CH₃)₂OH)→HO(CH₃)₂C—C≡C-Q-C≡C—C(CH₃)₂OH+2HL (c)

HO(CH₃)₂C—C≡C-Q-C—C≡C—C(CH₃)₂OH→H—C≡C-Q-C≡C—H+2O═C(CH₃)₂ (d)

The “Q” and the “L” represent the same symbols as those in the above-stated reaction formula (a). The reaction represented by the reaction formula (c) is the coupling reaction, and it is possible to be performed under similar conditions as the coupling reaction represented by the above-stated reaction formula (a) or (b).

The reaction represented by the reaction formula (d) is a generation reaction of the ethynyl group resulting from desorption of acetone, and it is generally performed under a basic condition. Potassium hydroxide, sodium hydroxide, calcium hydroxide, potassium carbonate, sodium carbonate, and so on can be cited as a used base, and it is preferable to use potassium hydroxide and sodium hydroxide from a point of view of strength of the basic. Besides, this reaction is preferable to be performed while quickly removing generated acetone from a system, and further, it is preferable to be performed while heating at a reduced pressure. As a reaction pressure, it is preferable to be within a range of 0.01 Pa to 0.5 Pa, and more preferable to be performed within a range of 0.3 Pa to 0.5 Pa. A reaction temperature is preferable to be performed at 30° C. to 200° C., and it is more preferable to be performed by heating to approximately 100° C. to 150° C.

A compound represented by the formula: H—C≡C—Ar^{F}(Z)ₖ in the reaction formula (b) can be manufactured by the similar method.

(II) A method using a nucleophilic substitution reaction accompanied by desorption of the fluorine atom represented by the following reaction formula

M-C≡C-Q-C≡C-M+2(F—Ar^{F}(Z)ₖ)→(Z)ₖAr^{F}—C≡C-Q-C≡C—Ar^{F}(Z)ₖ+2MF (e)

The “Q”, the Ar^{F} and the (Z)ₖ represent the same symbols as those in the above-stated reaction formula (a). The “M” represents a monovalent metal atom. As the monovalent metal “M”, lithium, potassium, sodium, and so on can be used. The nucleophilic substitution reaction is preferable to be performed under a low temperature and in an aprotic polar solvent. It is preferable to be performed at a reaction temperature of −80° to 10° C., and it is more preferable to be performed at −20° to 5° C. It is preferable to use an aprotic polar solvent as the reaction solvent. Specifically, for example, diethylether, tert-butylmethylether, tetrahydrofuran, dimethylformamide, dimethylacetamide, dimethylsulfoxide are used.

Next, the organic semiconductor material according to a second embodiment of the present invention is described. The organic semiconductor material according to the second embodiment of the present invention is the organic semiconductor material containing the above-stated fluorine-containing aromatic compound (1). The organic semiconductor material is good as long as it contains the fluorine-containing aromatic compound (1), and the fluorine-containing aromatic compound (1) may be used by mixing with the other organic semiconductor material, or it may contain various kinds of dopants. For example, coumarin, quinacridone, rubrene, a stilbene based derivative, a fluorescent dye, and so on can be used as the dopants when it is used as, for example, a light emitting layer of the organic EL element.

Next, the organic thin film device according to a third embodiment of the present invention is described. The organic thin film device according to the third embodiment of present invention has the organic semiconductor material according to the second embodiment. The organic thin film device according to the embodiment includes at least one organic layer, and at least one layer among the organic layers contains the above-stated fluorine-containing aromatic compound (1).

The organic thin film device according to the embodiment is able to have various aspects, and the organic TFT can be cited as one of suitable aspects.

In the fluorine-containing aromatic compound (1), the fluorine-containing aromatic hydrocarbon group represented by the Ar^{F} and the monocyclic, polycyclic assembly or condensed polycyclic structure of the benzene ring or the heterocycle represented by the “Q” are regularly arranged for some extent, and therefore, the fluorine-containing aromatic compound (1) is easy to have an arrangement in which the molecules are alternately stacked and laminated with each other owing to an interaction between the fluorine-containing aromatic hydrocarbon group and the ring structure. Accordingly, the interaction between molecules is large, and the high carrier mobility can be expected because 7 electron orbits overlap between the molecules with each other. Therefore, it is possible to enable large field effect mobility characteristics by using this material for an organic semiconductor layer (called also as an “organic active layer”) of the organic TFT (field effect transistor).

More specifically, an aspect in which the organic semiconductor layer contains the above-stated fluorine-containing aromatic compound (1) in the organic thin film device having the organic TFT can be cited as the organic thin film device, the organic thin film device including a substrate, a gate electrode, a gate insulating layer, a organic semiconductor layer, a source electrode and a drain electrode on the substrate.

As stated above, the fluorine-containing aromatic compound (I) is able to attain the high carrier mobility because of the large interaction between the molecules owing to the interaction between the fluorine-containing aromatic hydrocarbon group represented by the Ar^{F} and the monocyclic, polycyclic assembly or condensed polycyclic structure of the benzene ring or the heterocycle represented by the “Q”, and therefore, it is effective when it is used for the organic semiconductor layer (organic active layer) of the organic TFT.

Besides, the fluorine-containing aromatic compound (1) has high electron acceptability owing to an effect of an electron affinity of the fluorine-containing hydrocarbon group, and has the electron transport properties, and therefore, it can be used as an n-type semiconductor.

In the organic TFT being an aspect of the organic thin film device, the substrate is not particularly limited, and for example, it can be a conventionally publicly known constitution. For example, substrates made up of glass (for example, quartz glass), silicon, ceramics, plastic can be cited. For example, substrates made up of general resins such as polyethylene terephtalate, polyethylene naphthalate, polycarbonate (resin substrates) can be cited as the plastic substrates. As the resin substrate, it is preferable to be the one in which a gas barrier film to lower a transmitting property of gas such as oxygen, vapor is laminated.

The gate electrode is not particularly limited, and it can be a conventionally publicly known constitution. The gate electrode is able to be constituted by materials such as a metal, for example gold, platinum, chromium, tungsten, tantalum, nickel, copper, aluminum, silver, magnesium, calcium or an alloy thereof, polysilicon, amorphous silicon, graphite, tin-doped indium oxide (hereinafter, referred to as “ITO”), zinc oxide, conductive polymer.

The gate insulating layer is not particularly limited, and it can be a conventionally publicly known constitution. Materials such as SiO₂, Si₃N₄, SiON, Al₂O₃, Ta₂O₅, amorphous silicon, polyimide resin, polyvinyl phenol resin, polyparaxylene resin, polymethyl methacrylate resin, fluorocarbon resins (PTFE, PFA, PETFE, PCTFE, CYTOP (registered trademark) can be used as the gate insulating layer.

The organic semiconductor layer is not particularly limited as long as it is a layer containing the fluorine-containing aromatic compound (1). For example, it may be a layer practically made up of only the fluorine-containing aromatic compound (1), or a layer containing the other substances other than the fluorine-containing aromatic compound (1).

The source electrode and the drain electrode are both not particularly limited, and they may be conventionally publicly known constitutions. The source electrode and the drain electrode are both able to be constituted by materials such as metals such as gold, platinum, chromium, tungsten, tantalum, nickel, copper, aluminum, silver, magnesium, calcium or an alloy thereof, polysilicon, amorphous silicon, graphite, ITO, zinc oxide, conductive polymer.

A constitution of a lamination of the organic TFT may be any one of (1) a constitution in which the gate electrode, the gate insulating layer, the organic semiconductor layer, the source electrode and the drain electrode are held in this sequence from the substrate side, (2) a constitution in which the gate electrode, the gate insulating layer, the source electrode and the drain electrode, and the organic semiconductor layer are held in this sequence from the substrate side, (3) a constitution in which the organic semiconductor layer, the source electrode and the drain electrode, the gate insulating layer, and the gate electrode are held in this sequence from the substrate side, and (4) a constitution in which the source electrode and the drain electrode, the organic semiconductor layer, the gate insulating layer, the gate electrode are held in this sequence from the substrate side.

A manufacturing method of the organic TFT is not particularly limited. In case of the constitution (1), for example, a top contact source-drain method in which the gate electrode, the gate insulating layer, the organic semiconductor layer, the drain electrode and the source electrode are sequentially laminated on the substrate can be cited. In case of the constitution (2), a bottom contact source-drain method in which the gate electrode, the gate insulating layer, the drain electrode and the source electrode, and the organic semiconductor layer are sequentially laminated on the substrate can be cited. Besides, in cases of the constitution (3) and the constitution (4), a top gate type manufacturing method can also be cited.

Forming methods of the gate electrode, the gate insulating layer, the source electrode and the drain electrode are not particularly limited. All of them are able to be formed by, for example, well-known film forming methods such as a vacuum deposition method, an electron beam evaporation method, an RF sputtering method, a spin coating method, and a printing method by using the above-stated materials.

A forming method of the organic semiconductor layer is not particularly limited. It can be formed by the well-known film forming methods such as the vacuum deposition method, the spin coating method, the ink-jet method, and the printing method by using the above-stated fluorine-containing aromatic compound (1). In particular, the fluorine-containing aromatic compound (1) is soluble for the general organic solvents such as chloroform, tetrahydrofuran, toluene, xylene, and therefore, it is possible to form the thin film by the low-cost coating methods such as the spin coating method, the ink-jet method, and the printing method.

Usages of the organic thin film device according to the third embodiment having the organic TFT are not particularly limited. For example, it is suitably used as a driving TFT of a flexible display having the plastic substrate.

In general, there is a difficulty involved in a process to manufacture the TFT constituted by inorganic substance on a film state plastic substrate. However, in a manufacturing process of the organic thin film device according to the third embodiment having the organic TFT, the organic semiconductor layer is formed by using the vacuum deposition method, the spin coating method, the ink-jet method, the printing method, and so on as stated above, and a high-temperature process is not used. Accordingly, it is possible to form a pixel driving TFT on the plastic substrate. In particular, the fluorine-containing aromatic compound (1) according to the first embodiment is soluble for the general organic solvents such as chloroform, tetrahydrofuran, toluene, xylene, and therefore, the low-cost processes such as the spin coating method, the ink-jet method, and the printing method are applicable, and it is suitable for manufacturing of a low-cost paper-like (flexible) display.

As one of the other aspects of the organic thin film device containing the fluorine-containing aromatic compound (1) according to the first embodiment, the organic EL element can be cited. Specifically, an aspect in which an organic thin film device includes the organic EL element having a substrate, an anode, one layer or more of organic compound layers, and a cathode formed on the substrate, and the organic compound layer contains the above-stated fluorine-containing aromatic compound (1) can be cited.

In the organic EL element being an aspect of the organic thin film device, the substrate is not particularly limited, and it may have a conventionally publicly known constitution. As constitution materials of the substrate, for example, it is preferable to use transparent materials such as glass and plastic. Besides, it is possible to use a material other than the transparent material, for example, silicon when transparency is added to the cathode to take light-emission from the cathode side.

The anode is not particularly limited, and it may have a conventionally publicly known constitution. Specifically, it is preferable to use materials transmitting light as anode constitution materials. More specifically, the anode constitution materials are preferable to be ITO, indium oxide, tin oxide, zinc oxide. Besides, metal thin films such as gold, platinum, silver, magnesium alloy; polymer organic materials such as polyaniline, polythiophene, polypyrrole, derivatives thereof can also be used.

The cathode is not particularly limited, and it may have a conventionally publicly known constitution. Specifically, it is preferable to constitute the cathode by alkali metals such as Li, K, Na of which work functions are low; alkaline earth metals such as Mg, Ca from a point of view of electron injection properties. Besides, it is also preferable to use halides of alkali metals such as LiF, LiCl, KF, KCl, NaF, NaCl and a stable metal such as Al provided thereon as cathode constitution materials.

The organic compound layer has a lamination structure of one layer or two or more layers. A layer structure of the organic compound layer is not particularly limited, and for example, it may have a conventionally publicly known constitution. For example, a one layer structure made up of a light-emitting layer; a two-layer structure made up of a hole transport layer/light-emitting layer; a two-layer structure made up of a light-emitting layer/electron transport layer; a three-layer structure made up of a hole transport layer/light-emitting layer/electron transport layer; a four-layer structure made up of a hole injection layer/hole transport layer/light-emitting layer/electron injection layer; a five-layer structure made up of a hole injection layer/hole transport layer/light-emitting layer/electron transport layer/electron injection layer from the anode side to the cathode side can be typically cited as the organic compound layer.

As stated above, the organic compound layer contains the above-stated fluorine-containing aromatic compound (1). At least one layer from among the respective layers used in the above-stated various layer structures of the organic compound layer may contain the fluorine-containing aromatic compound (1). For example, at least one layer selected from the hole injection layer, the hole transport layer, the light-emitting layer, the electron transport layer, and the electron injection layer may contain the fluorine-containing aromatic compound (1) in case of the above-stated five-layer structure.

In the organic compound layer, one kind may be used or two or more kinds may be used together as the above-stated fluorine-containing aromatic compound (1). Besides, in the organic compound layer, a luminescent organic compound other than the fluorine-containing aromatic compound (1) may be used together. The luminescent organic compound other than the fluorine-containing aromatic compound (1) is not particularly limited, and for example, a conventionally publicly known one can be used.

The organic compound layer may have a conventionally publicly known constitution in each layer other than at least one layer contains the fluorine-containing aromatic compound (1). Hereinafter, a case when the organic compound layer is the five-layer structure is described as an example. Note that the embodiment is not limited thereto.

As materials constituting the hole injection layer or the hole transport layer, conductive polymer materials such as a phthalocyanine derivative, a naphthalocyanine derivative, a porphyrin derivative, an aromatic tertiary amine derivative, stilbene, polyvinyl carbazole, polythiophene, polyaniline, and compounds containing a skeletal structure or a substituent having high electron releasing properties are suitably exemplified. In particular, compounds easy to inject the holes from the anode and of which ionization potential is small are preferable as the materials constituting the hole injection layer. Besides, compounds of which ionization potential is equivalent to the light-emitting layer are preferable as the materials constituting the hole transport layer.

For example, metal complexes such as a quinoline metal complex, an aminoquinoline metal complex, a benzoquinoline metal complex; condensed polycyclic compounds such as anthracene, phenanthrene, pyrene, tetracene, coronene, chrysene, perylene can be cited as light-emitting materials or host materials constituting the light-emitting layer. Besides, coumarin, quinacridone, rubrene, a stilbene based derivative, a fluorescent dye, and so on may be doped into the light-emitting layer for a very small quantity.

For example, oxadiazole, triazole, phenanthrone, bathocuproin, a quinoline complex, perylenetetracarboxylic acid, derivatives thereof, or the like can be cited as materials constituting the electron transport layer or the electron injection layer, but they are not limited thereto. These layers may be each constituted from two or more layers.

For example, a constitution in which the anode, the organic compound layer having the lamination structure of one layer or two or more layers, and the cathode are held in this sequence from the substrate side, a constitution in which the cathode, the organic compound layer having the lamination structure of one layer or two or more layers, and the anode are held in this sequence from the substrate side can be cited as a lamination constitution of each layer in the organic EL element.

A manufacturing method of the organic EL element is not particularly limited. For example, a method in which the anode, the organic compound layer, and the cathode are sequentially laminated on the substrate; a method in which the cathode, the organic compound layer, and the anode are sequentially laminated on the substrate can be cited.

Formation methods of the anode and the cathode are not particularly limited. Both can be formed by well-known film forming methods such as the vacuum deposition method, the electron beam evaporation method, the RF sputtering method, the spin coating method, the ink-jet method, the printing method, a spraying method by using the above-stated materials.

A formation method of the organic compound layer is not particularly limited. The layer containing the above-stated fluorine-containing aromatic compound (1) is able to be formed by the well-known film forming methods such as the vacuum deposition method, the spin coating method, the printing method by using the fluorine-containing aromatic compound (1). Besides, the layer which does not contain the fluorine-containing aromatic compound (1) is able to be formed by the well-known film forming methods such as the vacuum deposition method, the electron beam evaporation method, the RF sputtering method, the spin coating method, the ink-jet method, the printing method, the spraying method by using the above-stated materials.

In general, when a voltage is applied between the anode and the cathode of the organic EL element, the holes are injected from the anode into the light-emitting layer via the hole injection layer and the hole transport layer, and the electrons are injected from the cathode into the light-emitting layer via the electron injection layer and the electron transport layer. The holes and the electrons are recombined at the light-emitting layer, molecules of luminescent organic compound contained in the light-emitting layer are excited by energy generated at that time, and excitons are generated. Luminous phenomenon occurs during a process in which the generated excitons are deactivated into a ground state.

Conventionally, reduction in a driving voltage and increase in luminous quantum efficiency are important problems when the organic EL element is practically used. To solve this problem, it is required to effectively take the holes from the anode to inject into the light-emitting layer, to effectively take the electrons from the cathode to inject into the light-emitting layer, and to effectively transport the holes and the electrons to the light-emitting layer without any loss.

In the embodiment, the fluorine-containing aromatic compound (1) is excellent in transport properties of the holes and the electrons, and therefore, it is effective to use the fluorine-containing aromatic compound (1) for at least one layer among the hole injection layer, the hole transport layer, the electron injection layer and the electron transport layer of the organic EL element. Besides, it is also preferable to use the fluorine-containing aromatic compound (1) for the light-emitting layer because it is necessary to inject both of the holes and the electrons into the light-emitting layer and to recombine them.

As stated above, the fluorine-containing aromatic compound (I) having the high carrier mobility is used for at least one layer from among the hole injection layer, the hole transport layer, the electron injection layer, the electron transport layer, and the light-emitting layer of the organic EL element, and thereby, it becomes possible to effectively inject the holes and the electrons into the light-emitting layer, and to increase light-emitting efficiency and to decrease the driving voltage.

Usages of the organic thin film device according to the embodiment having the organic EL element are not particularly limited. For example, it is suitably used for an organic EL display device. The organic EL display device includes an organic EL display element disposing the organic EL elements to be pixels in plural.

For example, a passive type organic EL element has a structure in which the organic compound layer including the light-emitting layer is sandwiched between an intersection part of anode wirings disposed in a stripe state and cathode wirings disposed in a stripe state to intersect with the anode wirings, a pixel as a light-emitting element is formed by each intersection part, and the pixels are arranged in a matrix state. Besides, elements in which a switching organic TFT is combined with the organic EL element are disposed in a matrix state, and thereby, an active type organic EL display element is enabled.

In the organic thin film device according to the embodiment, it is possible to use the plastic substrate in addition to the glass substrate as the substrate of the electric device such as the transistor and the optical device such as the organic EL element. The plastics made of the substrate are preferable to be excellent in heat resistance, dimensional stability, solvent resistance, electric insulation, processability, low air permeability, and low hygroscopicity. Polyethylene terephtalate, polyethylene naphthalate, polystyrene, polycarbonate, polyacrylate, polyimide, and so on can be cited as the plastics as stated above.

In the organic thin film device according to the embodiment, it is preferable to have a structure in which a moisture permeation preventing layer (gas barrier layer) is included at one of or both of a surface at an electrode side and a surface at an opposite side of the electrode of a substrate. As materials constituting the moisture permeation preventing layer, inorganic substances such as silicon nitride, silicon dioxide are suitably exemplified. The moisture permeation preventing layer is able to be formed by the well-known film forming method such as the RF sputtering method. The organic thin film device according to the embodiment may include a hard coat layer and an under coat layer according to need.

The organic thin film device according to the embodiment may have various aspects other than the above-stated organic TFT and organic EL. For example, an organic thin film solar cell is one of the other suitable aspects of the organic thin film device containing the fluorine-containing aromatic compound (1) according to the embodiment. Besides, the fluorine-containing aromatic compound (1) has the liquid crystallinity in the wide temperature range (for example, 10° C. to 300° C.), and therefore, a thin film device in which an optical anisotropic film is formed by using the fluorine-containing aromatic compound (1) can be cited as one of the other suitable aspects of the organic thin film device.

Usages of the organic thin film device according to the embodiment are not particularly limited, and it is possible to use for wide usages such as a display device, a display element, a backlight, an optical communication, an electrophotography, an illumination light source, a record light source, an exposure light source, a read light source, a sign marker, an advertising display, an interior, a battery.

### EXAMPLES

Hereinafter, the present invention is described more concretely by examples, but the present invention is not limited to these examples.

### Synthesis of Intermediate (2,6-diethynylnaphthalene)

Synthesis of 2,6-diethynylnaphthalene was performed in accordance with the following reaction formulas (A) and (B) as an intermediate used for a synthesis of later-described fluorine-containing aromatic compounds (II), (12).

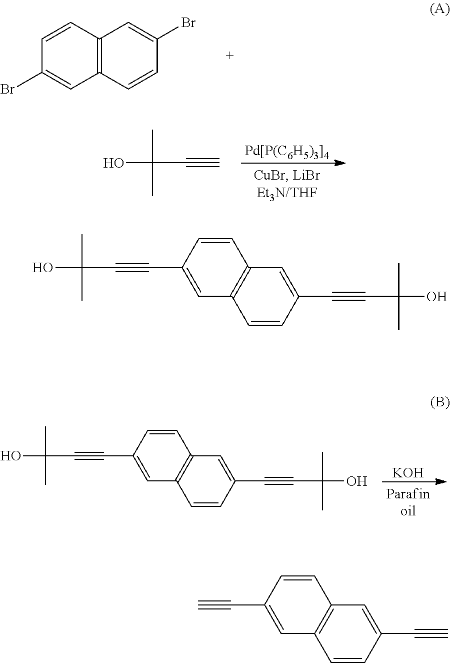

A concrete synthesis method of 2,6-diethynylnaphthalene is represented in the following. Preparing 20.15 g of 2,6-dibromonaphthalene, 2.0 g of tetrakis (triphenylphosphine) palladium (0) and 1.14 g of triphenylphosphine at a four-necked flask with a capacity of 300 mL equipped with a thermocouple thermometer and a mechanical stirrer, and a system was nitrogen substituted. Then 60 ml of triethylamine was prepared. Further, the one in which 0.15 g of copper bromide (I) and 0.59 g of lithium bromide were dissolved into 15 mL of tetrahydrofuran (hereinafter, referred to as “THF”) was prepared, and 23.9 g of 2-methylbuta-3-en-2-ol was added thereto.

The system was heated to 90° C. to 95° C., and stirred for two to three hours. Subsequently, a reaction system was cooled to a room temperature, and thereafter, 200 mL of 0.5 mol/L hydrochloric acid was input, and a precipitated solid body was filtered and collected. The collected solid body was cleaned by water, toluene, methanol in thwas sequence, and thereafter, a vacuum drying was performed at 50° C. for two hours, to obtain 16.0 g of almost pure 4,4′-(naphthalene-2,6-diyl)bis(2-methylbuta-3-en-2-ol) (yield: 77%) (refer to the above-stated reaction formula (A)).

A product obtained as stated above was poured into a four-necked flask with a capacity of 300 mL equipped with the thermocouple thermometer and the mechanical stirrer, 29.8 g of liquid paraffin and 13.4 g of ground potassium hydroxide were prepared thereto, stirred and dispersed. The system was reduced pressure to 0.23 Pa, and thereafter, heated to 100° C. to 130° C., and continued to heat and stir until foaming resulting from generation of acetone disappears. Next, 100 mL of dichloromethane and 100 mL of water were added and stirred, and thereafter, insoluble solid bodies were filtered and removed. A crude product was obtained as a mixture with the liquid paraffin by extracted with dichloromethane and condensed. It was refined by a column chromatography, and thereby, 7.3 g of almost pure 2,6-diethynylnaphthalene was obtained (yield: 86%) (refer to the above-stated reaction formula (B)). Note that 2,6-diethynylnaphthalene was identified by an analysis of ¹H-NMR. An analysis result is represented in the following.

¹H-NMR (300.4 MHz, solvent: deuterochloroform (CDCl₃), criteria: tetramethylsilane (TMS)) δ (ppm); 3.18 (s, 2H), 7.53 (d, 2H), 7.74 (d, 2H), 7.98 (s, 2H)

### Example 1

### (1-1) Synthesis of Fluorine-Containing Aromatic Compound (11)

Pouring 0.2 g of sodium hydroxide and 10 g of THF into a glass reactor with a capacity of 100 mL equipped with the thermocouple thermometer and the mechanical stirrer, cooling to “0” (zero)° C., and thereafter, the one in which 0.5 g of hexyl alcohol was dissolved into 3 g of THF was slowly dropped therein. After the dropping, it was stirred at the room temperature for one hour. It was cooled to “0” (zero)° C. again, then the one in which 1.5 g of bromoheptafluoronaphthalene was dissolved into 5 g of THF was dropped therein, and thereafter, it was stirred at the room temperature for two days. Next, a reaction solution was poured into water, and it was extracted by tert-butylmethylether. An organic phase was dried by magnesium sulfate, and it was filtered and condensed. After that, the condensate was refined by silica gel column chromatography (hexane), and thereby, 1.26 g of 2-bromo-6-hexyloxy hexafluoro naphthalene was obtained.

Next, 0.82 g of 2-bromo-6-hexyloxy hexafluoro naphthalene obtained as stated above, 0.1 g of 2,6-diethynylnaphthalene obtained by the above-stated method, 0.006 g of copper iodide, 0.03 g of tetrakis (triphenylphosphine) palladium (0), and 3 g of triethylamine were poured into a glass reactor of 20 mL, and the system was nitrogen substituted. The reaction system was heated to 90° C. and stirred for three hours. Next, the reaction solution was cooled to the room temperature, and thereafter, hydrochloric acid of 0.5 mol/L was added and extracted by chloroform. The organic phase was condensed, and thereafter, recrystallization was performed by 1/10 (mass ratio) mixed solution of hexane/chloroform, and 0.25 g of compound (yield: 50%) was obtained.

This compound was identified as 2,6-bis((6-hexyloxy hexafluoro naphthalene-2-yl)ethynyl)naphthalene having a chemical formula (11) represented in the following by each analysis of ¹H-NMR and ¹⁹F-NMR. Analysis results are represented in the following.

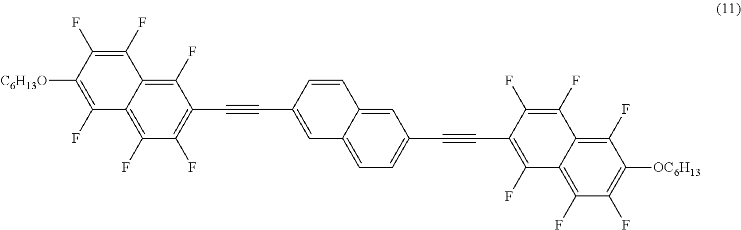

### NMR Spectra

¹H-NMR (399.8 MHz, solvent: deuterochloroform (CDCl₃), criteria: tetramethylsilane (TMS)) δ (ppm); 0.92 (s, 6H), 1.45 (m, 12H), 1.83 (m, 4H), 4.35 (m, 4H), 7.68 (d, 2H), 7.86 (d, 2H), 8.14 (s, 2H).

¹⁹F-NMR (376.2 MHz, solvent: CDCl₃, criteria: CFCl₃) δ (ppm); −114.25 (2F), −135.43 (2F), −140.36 (2F), −145.90 (2F), −149.78 (4F).

### (1-2) Evaluation of Liquid Crystallinity of Fluorine-Containing Aromatic Compound (11)

A phase transition temperature as for the fluorine-containing aromatic compound (II) obtained by the synthesis example (1-1) was measured by a DSC (differential scanning calorimetry). The measurement was performed at a rate of heating of 10° C./min. It was verified that it was a liquid crystal material representing a phase transition from a crystal phase to a liquid crystalline phase at 200° C., and representing a phase transition from the liquid crystalline phase to an isotropic phase at 309° C.

Next, a cell of which cell gap was 0.5 μm was heated on a hot plate, the compound (II) heated to the isotropic phase was permeated into the cell by using a capillary action. The liquid crystal cell formed as stated above was observed by a polarizing microscope, and as a result, it turned out that the liquid crystalline phase represented by the fluorine-containing aromatic compound (II) was a nematic phase.

### (1-3) Evaluation of Coating Properties of Fluorine-Containing Aromatic Compound (II)

One mass % of orthodichlorobenzene solution of the fluorine-containing aromatic compound (II) obtained by the synthesis example (1-1) was prepared. The obtained solution was filtered with a PTFE (polytetrafluoroethylene) filter of which thickness was 0.45 μm, and thereafter, it was coated on a silicon substrate by the spin coating. A coating condition was 1500 rotations per minute for 30 seconds. Next, the silicon substrate was placed on the hot plate, and heated at 150° C. for 90 seconds. After that, a film thickness of a compound (II) layer formed on the silicon substrate was measured by using an AFM (atomic force microscope), and it was 70 nm.

It was thereby verified that the fluorine-containing aromatic compound (II) had a good solubility for general solvents, the low-cost coating method such as the spin coating could be used, and the thin film could be formed.

### Example 2

### (2-1) Synthesis of Fluorine-Containing Aromatic Compound (12)

Pouring 1.1 g of sodium hydroxide and 40 g of THF into a glass reactor with a capacity of 200 mL equipped with the thermocouple thermometer and the mechanical stirrer, it was cooled to “0” (zero) ° C., and thereafter, the one in which 2.5 g of hexyl alcohol was dissolved into 3 g of THF was slowly dropped therein. After the dropping, it was stirred at the room temperature for one hour. It was cooled to “0” (zero) ° C. again, 5.0 g of pentafluorobromobenzene was dropped therein, and thereafter, it was stirred at the room temperature for two hours. Next, a reaction solution was poured into water, and it was extracted by tert-butylmethylether. An organic phase was dried by magnesium sulfate, and it was filtered and condensed. After that, the condensate was refined by silica gel column chromatography (hexane), and thereby, 5.95 g of 4-hexyloxy tetrafluoro bromobenzene was obtained.

Next, 0.65 g of 4-hexyloxy tetrafluoro bromobenzene obtained as stated above, 0.1 g of 2,6-diethynylnaphthalene obtained by the above-stated method, 0.007 g of copper iodide, 0.026 g of tetrakis (triphenylphosphine) palladium (0), and 5 g of triethylamine were poured into a glass reactor of 20 mL, the system was nitrogen substituted, and thereafter, it was heated to 90° C. and stirred for two hours. Next, the reaction solution was cooled to the room temperature, and thereafter, hydrochloric acid of 0.5 mol/L was added and extracted by chloroform. The organic phase was condensed, and thereafter, it was refined by silica gel column chromatography (hexane→hexane/chloroform (6:1)), and thereby, 0.18 g of compound (yield: 45%) was obtained.

This compound was identified as 2,6-bis((4-hexyloxy tetrafluorophenyl)ethynyl)naphthalene having a chemical formula (12) represented in the following by each analysis of ¹H-NMR and ¹⁹F-NMR. Analysis results are represented in the following.

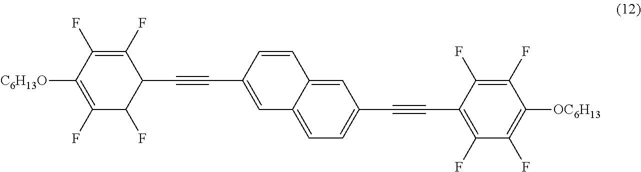

### NMR Spectra

¹H-NMR (399.8 MHz, solvent: CDCl₃, criteria: TMS) δ (ppm); 1.02 (s, 6H), 1.46 (m, 12H), 1.90 (m, 4H), 4.39 (m, 4H), 7.72 (d, 2H), 7.92 (d, 2H), 8.18 (s, 2H).

¹⁹F-NMR (376.2 MHz, solvent: CDCl₃, criteria: CFCl₃) δ (ppm); −138.35 (4F), −157.74 (4F).

### (2-2) Evaluation of Liquid Crystallinity of Fluorine-Containing Aromatic Compound (12)

The phase transition temperature as for the fluorine-containing aromatic compound (12) obtained by the synthesis example (2-1) was measured by the DSC (differential scanning calorimetry). The measurement was performed at the rate of heating of 10° C./min. As a result, it was verified that it was a liquid crystal material representing the phase transition from the crystal phase to the liquid crystalline phase at 130° C., and representing the phase transition from the liquid crystalline phase to the isotropic phase at 175° C.

Next, cell of which cell gap was 0.5 μm was heated on a hot plate, the fluorine-containing aromatic compound (12) heated to the isotropic phase was permeated into the cell by using the capillary action. The liquid crystal cell formed as stated above was observed by the polarizing microscope, and as a result, it turns out that the liquid crystalline phase represented by the fluorine-containing aromatic compound (12) was the nematic phase.

### (2-3) Evaluation of Coating Properties of Fluorine-Containing Aromatic Compound (12)

One mass % of orthodichlorobenzene solution of the fluorine-containing aromatic compound (12) obtained by the synthesis example (2-1) was prepared. The obtained solution was filtered with the PTFE (polytetrafluoroethylene) filter of which thickness was 0.45 μm, and thereafter, it was coated on the silicon substrate by the spin coating. The coating condition was 1500 rotations per minute for 30 seconds. Next, the silicon substrate was placed on the hot plate, and the heating process was performed at 120° C. for 120 seconds. After that, a film thickness of a compound (12) layer formed on the silicon substrate was measured by using the AFM (atomic force microscope), and it was 80 nm.

It was verified that the fluorine-containing aromatic compound (12) had good solubility for general solvents, the low-cost coating methods such as the spin coating could be used, and the thin film could be formed.

### (2-4) Evaluation of Semiconductor Properties (Carrier Mobility) of Fluorine-Containing Aromatic Compound (12)

A space charge limited current was measured to thereby evaluate presence/absence of the carrier mobility of the fluorine-containing aromatic compound (12). A PEDOT/PSS layer of 50 nm, the layer of the fluorine-containing aromatic compound (12) of 80 nm were sequentially formed on an ITO substrate of which surface was cleaned, by the spin coating method. Note that the PEDOT/PSS was a complex of poly(3,4-ethylenedioxythiophene) and polystyrene sulfonic acid, the complex being a conductive polymer material. Next, an aluminum layer of 50 nm was formed on a surface thereof by the vacuum deposition method. A lamination structure of the ITO-PEDOT/PSS—fluorine-containing aromatic compound (12)—aluminum obtained as stated above and a current-voltage meter were connected, a voltage (0.1 V to 2.0 V) was applied between the ITO-Al electrode, and a current measurement was performed. At a high potential region of an obtained J-V curve, it turned out that a value in proportion to a square of the applied voltage was represented. The current at the high potential region was considered to be the space charge limited current, and the fluorine-containing aromatic compound (12) was verified to have an electron mobility by the voltage application.

### Example 3

### (3-1) Synthesis of Fluorine-Containing Aromatic Compound (13)

Pouring 0.5 g of 5,5-dibromo-2,2: 5,2-terthiophene, 0.42 g of trimethylsilylacetylene, 0.005 g of copper iodide, 0.034 g of dichlorobistriphenylphosphine palladium, and 7 g of diisopropylamine into a glass reactor with a capacity of 200 mL equipped with the thermocouple thermometer and the mechanical stirrer, the system was nitrogen substituted, and thereafter, it was stirred at 70° C. for five hours. Subsequently, a reaction crude solution was condensed, and thereafter, it was extracted by tert-butylmethylether, water-washed, and an organic phase was condensed. Adding 11 mL of methanol, 15 mL of THF and 0.1 g of potassium fluoride thereto, then it was heated and stirred at 50° C. for five hours. The reaction solution was condensed, and thereafter, it was extracted by chloroform, then water-washed, and the organic phase was condensed. Next, it was refined by silica gel column chromatography (hexane→hexane/chloroform (10:1)), and thereby, 0.2 g of 5,5″-diethynyl-2,2′: 5′,2″-terthiophene was obtained.

Next, 0.1 g of 5,5″-diethynyl-2,2′: 5′,2″-terthiophene obtained as stated above, 0.39 g of 4-hexyloxy tetrafluoro bromobenzene, 0.002 g of copper iodide, 0.011 g of dichlorobistriphenylphosphine palladium, and 4 g of diisopropylamine were poured into a glass reactor, the system was nitrogen substituted, and thereafter, it was stirred at 90° C. for four hours. The reaction solution was cooled to the room temperature, and thereafter, hydrochloric acid of 0.5 mol/L was added and extracted by chloroform. The organic phase was condensed, and thereafter, it was refined by silica gel column chromatography (hexane→hexane/chloroform (5:1)), and thereby, 0.15 g of compound (yield: 50%) was obtained.

This compound was identified as 5,5″-bis((4-hexyloxy tetrafluorophenyl)ethynyl)-2.2°: 5,2″-terthiophene having a chemical formula (13) represented in the following by each analysis of ¹H-NMR and ¹⁹F-NMR. Analysis results are represented in the following.

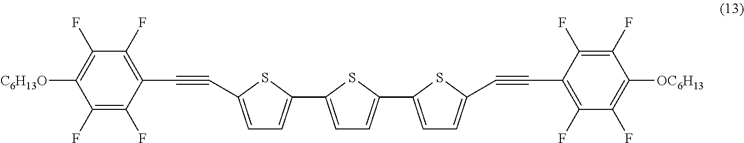

### NMR Spectra

¹H-NMR (399.8 MHz, solvent: CDCl₃, criteria: TMS) δ (ppm); 0.91 (m, 6H), 1.35 (m, 12H), 1.76 (m, 4H), 4.25 (m, 4H), 7.09 (m, 4H), 7.25 (m, 2H).

¹⁹F-NMR (376.2 MHz, solvent: deuterochloroform, criteria: CFCl₃) δ (ppm); −138.20 (4F), −157.66 (4F).

### (3-2) Evaluation of Liquid Crystallinity of Fluorine-Containing Aromatic Compound (13)

A phase transition temperature as for the fluorine-containing aromatic compound (13) obtained by the synthesis example (3-1) was measured by the DSC (differential scanning calorimetry). The measurement was performed at the rate of heating of 10° C./min. As a result, it was verified that it was a liquid crystal material representing the phase transition from the crystal phase to the liquid crystalline phase at 93° C., and representing the phase transition from the liquid crystalline phase to the isotropic phase at 194° C.

Next, a cell of which cell gap was 0.5 m was heated on the hot plate, the fluorine-containing aromatic compound (13) heated to the isotropic phase was permeated into the cell by using the capillary action. The liquid crystal cell formed as stated above was observed by the polarizing microscope, and as a result, it turned out that the liquid crystalline phase represented by the fluorine-containing aromatic compound (13) was the nematic phase.

### (3-3) Evaluation of Coating Properties of Fluorine-Containing Aromatic Compound (13)

One mass % of orthodichlorobenzene solution of the fluorine-containing aromatic compound (13) obtained by the synthesis example (3-1) was prepared. The obtained solution was filtered with the PTFE (polytetrafluoroethylene) filter of which thickness was 0.45 rpm, and thereafter, it was coated on the silicon substrate by the spin coating. The coating condition was 1500 rotations per minute for 30 seconds. Next, the silicon substrate was placed on the hot plate, and heated at 120° C. for 120 seconds. After that, a film thickness of a fluorine-containing aromatic compound (13) layer formed on the silicon substrate was measured by using the AFM (atomic force microscope), and it was 90 nm.

It was thereby verified that the fluorine-containing aromatic compound (13) had good solubility for general solvents, the low-cost coating methods such as the spin coating could be used, and the thin film could be formed.

The fluorine-containing aromatic compound and the organic semiconductor material according to the present invention have fine charge mobility properties as a charge transport material, in addition, they have a liquid crystallinity in a wide temperature range, and it is possible to form a uniform thin film in a large area by applying a low cost coating process, and therefore, it is possible to provide a high-performance organic TFT, organic EL element, and so on.

The present invention has been described in detail while referring to specific embodiments, but, it is obvious for a person skilled in the art that the invention can be variously modified and changed without departing from the scope and the spirit of the present invention.

What is claimed is:

1. A fluorine-containing aromatic compound represented by a following formula (1):
QW—Ar^{F}(Z)ₖ)ₙ (1)
wherein symbols in the formula (1) are as follows:
Q: an n-valent aromatic hydrocarbon group having a ring structure selected from a monocyclic structure made up of one benzene ring or one heterocycle containing a hetero atom, a polycyclic assembly structure in which two or more pieces of benzene rings or heterocycles are bonded in a single bond, and a condensed polycyclic structure of two or more pieces of benzene rings or heterocycles, and obtained by removing n-pieces of hydrogen atoms bonded to carbon atoms constituting the ring;
n: two or three;
W: a divalent hydrocarbon group having an unsaturated bond of which carbon number is two;
Ar^{F}: a “k+1”-valent fluorine-containing aromatic hydrocarbon group being a “k+1”-valent group having a monocyclic structure made up of one benzene ring or a condensed polycyclic structure of two or more pieces of benzene rings, and obtained by removing “k+1” pieces of hydrogen atoms bonded to the carbon atoms constituting the ring, and one or more pieces of hydrogen atoms bonded to the carbon atoms constituting the ring are substituted by fluorine atoms;
k: an integer number from one to three; and
Z: a monovalent organic group selected from —R, —OR, —CH₂—OR, —R^{f}, —O—(CH₂)—R^{f}, —CH₂—O—(CH₂)—R^{f}, in which the “R” is an alkyl group of which carbon number is one to 12, the “R^{f}” is a fluorine-substituted alkyl group of which carbon number is one to 12, and the “p” is an integer number from “0” (zero) to two.

2. The fluorine-containing aromatic compound according to claim 1, wherein, in the above-stated formula (1), the “n” is two, and two pieces of (W—Ar^{F}(Z)ₖ) units are identical.

3. The fluorine-containing aromatic compound according to claim 1, wherein in the formula (1), the “Q” is an n-valent aromatic hydrocarbon group obtained by removing n-pieces of hydrogen atoms from naphthalene or terthiophene.

4. The fluorine-containing aromatic compound according to claim 1, wherein in the formula (1), the “W” is an ethylenedene group represented by a following formula:
—C≡C—.

5. The fluorine-containing aromatic compound according to claim 1, wherein in the formula (1), the Ar^{F} is “k+1”-valent perfluoro aromatic hydrocarbon group.

6. The fluorine-containing aromatic compound according to claim 1, wherein in the formula (1), the “k” is one, and the “k+1”-valent fluorine-containing aromatic hydrocarbon group is tetrafluoro-1,4-phenylene group or hexafluoro-2,6-naphthylene group.

7. The fluorine-containing aromatic compound according to claim 1, wherein in the formula (1), the “k” is one, and the “Z” is —OR or —R^{f}.

8. An organic semiconductor material, comprising the fluorine-containing aromatic compound according to claim 1.

9. An organic thin film device, comprising a substrate and an organic thin film transistor having a gate electrode, a gate insulating layer, an organic semiconductor layer, a source electrode and a drain electrode formed on the substrate,
wherein the organic semiconductor layer contains the fluorine-containing aromatic compound according to claim 1.

10. An organic thin film device, comprising a substrate and an organic EL element including an anode, an organic compound layer having a one-layer or more structure, and a cathode formed on the substrate,
wherein the organic compound layer contains the fluorine-containing aromatic compound according to claim 1.
